(19) United States
(12) Patent Application Publication
(10) Pub. No.: US 2025/0244803 A1
(43) Pub. Date: Jul. 31, 2025

(54) CARRIER MODULE TO PROVIDE A THERMAL SOLUTION FOR STACKED COMPRESSION ATTACHED MEMORY MODULES

(71) Applicant: DELL PRODUCTS L.P., Round Rock, TX (US)

(72) Inventors: Arnold Thomas Schnell, Hutto, TX (US); Jing-Tang Wu, Xizhi District (TW); Chun-Kai Tzeng, KeeLung City (TW); Ting-Chiang Huang, New Taipei City (TW); Hao-Wu Yang, Zhongzheng District (TW); Yao-Fu Huang, New Taipei City (TW)

(21) Appl. No.: 18/428,952

(22) Filed: Jan. 31, 2024

(51) Int. Cl. G06F 1/18; G06F 1/20; H05K 7/20; H05K 9/00

(52) U.S. Cl. CPC G06F 1/185; G06F 1/20; H05K 7/20136; H05K 9/0032

(57) ABSTRACT

A holder is provided for stacked compression attached memory modules (CAMMs). The holder includes a carrier and a shield can. The carrier includes a first recessed area for receiving a bottom one of the CAMMs, a second recessed area for receiving a top one of the CAMMs, and a first vent hole in a side of the carrier. The shield can is configured to fit atop the carrier, and includes a second vent hole in a side of the shield can. The second vent hole is collocated with the first vent hole. The first vent hole and the second vent hole are provided to cool the bottom CAMM and the top CAMM.

### CROSS REFERENCE TO RELATED APPLICATIONS

This application is related to U.S. patent application Ser. No. 18/313,816, entitled “I-BEAM HOLDER FOR COMPRESSION ATTACHED MEMORY MODULES,” by Arnold Thomas Schnell et al., filed on May 8, 2023, which is hereby incorporated by reference.

Related subject matter is contained in co-pending U.S. patent application Ser. No. ______ (DC-135889) entitled “CARRIER MODULE FOR STACKED COMPRESSION ATTACHED MEMORY MODULES,” by Arnold Thomas Schnell et al., filed of even date herewith, the disclosure of which is hereby incorporated by reference.

Related subject matter is contained in co-pending U.S. patent application Ser. No. ______ (DC-137463) entitled “CARRIER MODULE FOR GROUNDING STACKED COMPRESSION ATTACHED MEMORY MODULES,” by Arnold Thomas Schnell et al., filed of even date herewith, the disclosure of which is hereby incorporated by reference.

### FIELD OF THE DISCLOSURE

This disclosure generally relates to information handling systems, and more particularly relates to a carrier module for grounding stacked compression attached memory modules (CAMMs).

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

A holder for stacked compression attached memory modules (CAMMs) may include a carrier and a shield can. The carrier may include a first recessed area for receiving a bottom one of the CAMMs, a second recessed area for receiving a top one of the CAMMs, and a first vent hole in a side of the carrier. The shield can may be configured to fit atop the carrier, and may include a second vent hole in a side of the shield can. The second vent hole may be collocated with the first vent hole. The first vent hole and the second vent hole may be provided to cool the bottom CAMM and the top CAMM.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1A is a top view of an information handling system as is known in the prior art;

FIG. 1B is a side view of the information handling system of FIG. 1A;

FIGS. 2A-2F are various perspective views of a CAMM holder assembly for stacked CAMMs according to an embodiment of the current disclosure;

FIGS. 3A-3G are perspective views illustrating the assembly of an information handling system utilizing the CAMM holder assembly of FIGS. 2A-2F;

FIGS. 4A-4C illustrate various cut-away views of the assembly of FIGS. 3A-3G; and

FIG. 5 is a block diagram illustrating a generalized information handling system according to another embodiment of the present disclosure;

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

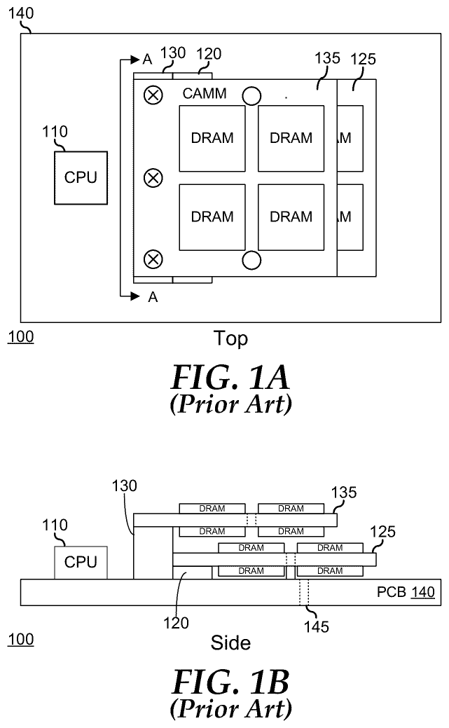

FIG. 1A illustrates an information handling system 100 as may be known in the prior art. Information handling system 100 includes a processor 110, and a compression connector 120 assembled onto a printed circuit board (PCB) 140, and a compression connector 130 assembled onto the PCB. Compression connector 130 is located proximate to processor 110 and compression connector 120 is located further from the processor and adjacent to compression connector 130. Compression connector 120 is populated with a compression attached memory module (CAMM) which includes memory devices populated on a CAMM PCB 125, and compression connector 130 is populated with a CAMM which includes memory devices populated on a CAMM PCB 135. Due to the locations of compression connectors 120 and 130, the configuration of information handling system 100 is said to include “stacked” CAMMs, with CAMM PCB 120 located partially under CAMM PCB 130.

Compression connectors 120 and 130 represents z-axis, or “vertical,” compression connectors that provide stand-offs from PCB 140. Compression connectors 120 and 130 include separate metal contact elements on a top surface of the compression connector, one for each signal line and power line. CAMM PCBs 125 and 135 each include surface contact connections that are compressed to engage with the contact elements of respective compression connectors 120 and 130. Examples of compression connectors may include cStack or mezzanine-type connectors from Amphenol, PCBeam connectors from Neoconix, or the like.

The memory devices on CAMM PCBs 125 and 135 represent fifth generation DDR (DDR5) memory devices. In a typical case, PCB 140 is configured with an interface pad arrangement to accommodate a single compression connector and a dual-channel DDR5 CAMM (not illustrated). However, in the current example, the single interface pad arrangement is utilized to accommodate compression connectors 120 and 130, and each of the compression connectors is arranged to carry only one of the two (2) DDR5 channels. As such the memory devices on each of CAMM PCBs 125 and 135 are accessed by CPU 110 via only one of the first memory channel or the second memory channel. In this case, they use stackable CAMMs that each only utilize one of the DDR5 memory channels may be based upon a design choice to provide a low-cost design. In this embodiment, compression connectors 120 and 130 still include contact elements associated only one memory channel, and the memory devices on CAMM PCBs 125 and 135 are configured to utilize only one of the memory channels.

FIG. 1B shows that CAMM PCB 135 is affixed to compression connector 130 by three (3) screws. Such a mechanism for attaching CAMM PCB 135 to compression connector 130 may include other elements, as needed or desired. While not directly illustrated CAMM PCB 125, due to the extended length of the CAMM PCB, is affixed to compression connector 120 by three (35) screws, similar to CAMM PCB 135, and by an additional two (2) screws to PCB 140 to support the extended length of the CAMM PCB. Due to the presence of CAMM PCB 125 below CAMM PCB 135, there is no way to support the extended length of CAMM PCB 135 utilizing similar screws. Compression connectors 120 and 130, and PCB 140 may include through-holes through which the screws pass, and bolts may be affixed to the screws on the bottom side of the PCB, as needed or desired. The attachment mechanism may include a bolster on the bottom side of PCB 130, as needed or desired.

The stacked CAMM arrangement as illustrated in FIGS. 1A and 1B above may be facilitated by the addition of CAMM holder assembly. In a typical arrangement, a bottom CAMM is assembled to a motherboard, and the CAMM holder assembly is installed atop the bottom CAMM. Then a top CAMM is assembled to the motherboard within the CAMM holder assembly, and a shield can is affixed to the CAMM holder assembly. Such a typical arrangement may suffer from several deficiencies which remain to be overcome. In particular, the typical CAMM holder assembly does not securely affix the top CAMM, but leaves the top CAMM cantilevered above the bottom CAMM. Further, ensuring an adequate shield grounding between the bottom CAMM, the top CAMM, and the shield can has been difficult in the typical arrangement. Finally, the typical arrangement subjects the memory devices of the CAMMs to excessive heating.

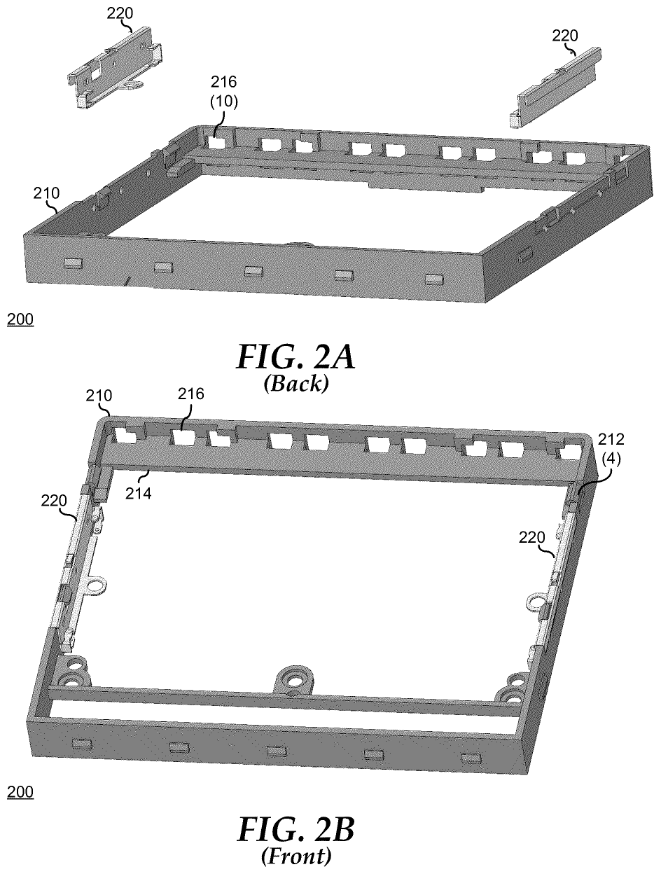

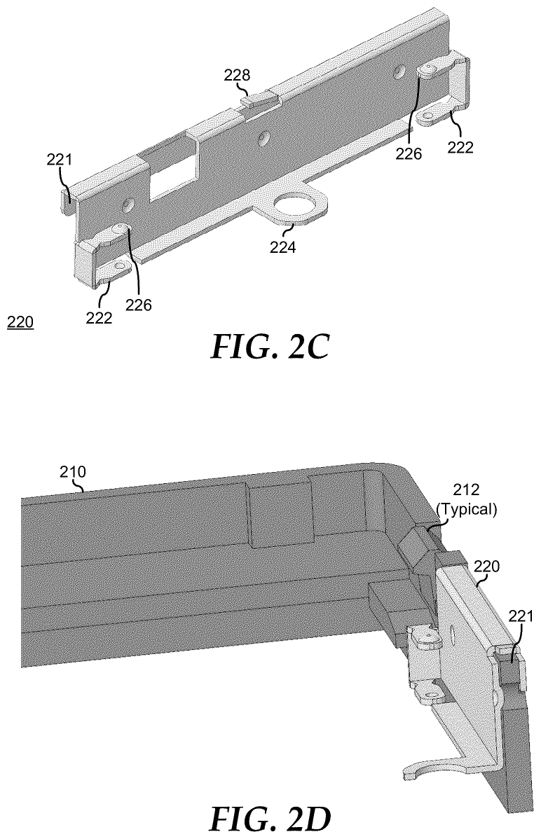

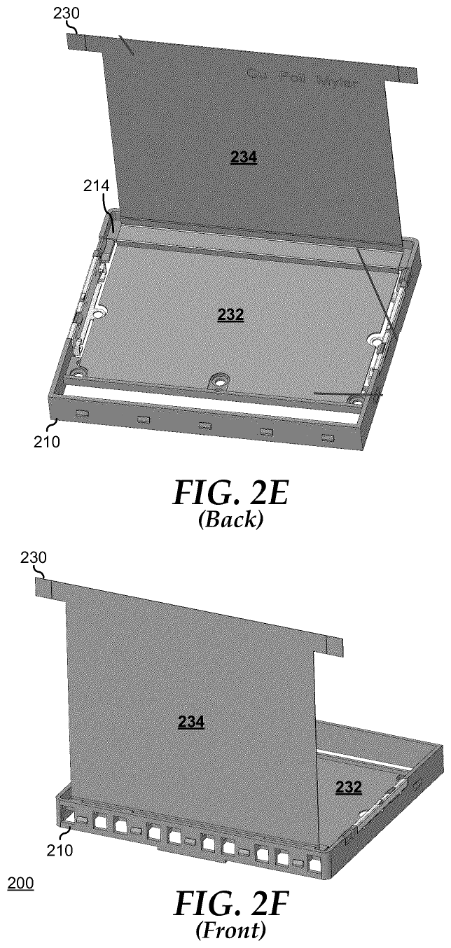

FIGS. 2A-2F illustrate a CAMM holder 200 for assembling stacked CAMMs to a motherboard. FIG. 2A illustrates a back view of CAMM holder 200 and FIG. 2B illustrates a front view of the CAMM holder. CAMM holder 200 includes a CAMM carrier 210 and metal ground/retention plates 220. CAMM carrier 210 includes top CAMM retention hooks 212, a foil mounting ledge 214, and vent holes 216. FIG. 2A illustrates where retention plates 220 are separate from CAMM carrier 210, and FIG. 2B illustrates where the retention plates are assembled to the side walls of the CAMM carrier. The functions and features of top CAMM retention hooks 212, foil mounting ledge 214, and vent holes 216 will be described below.

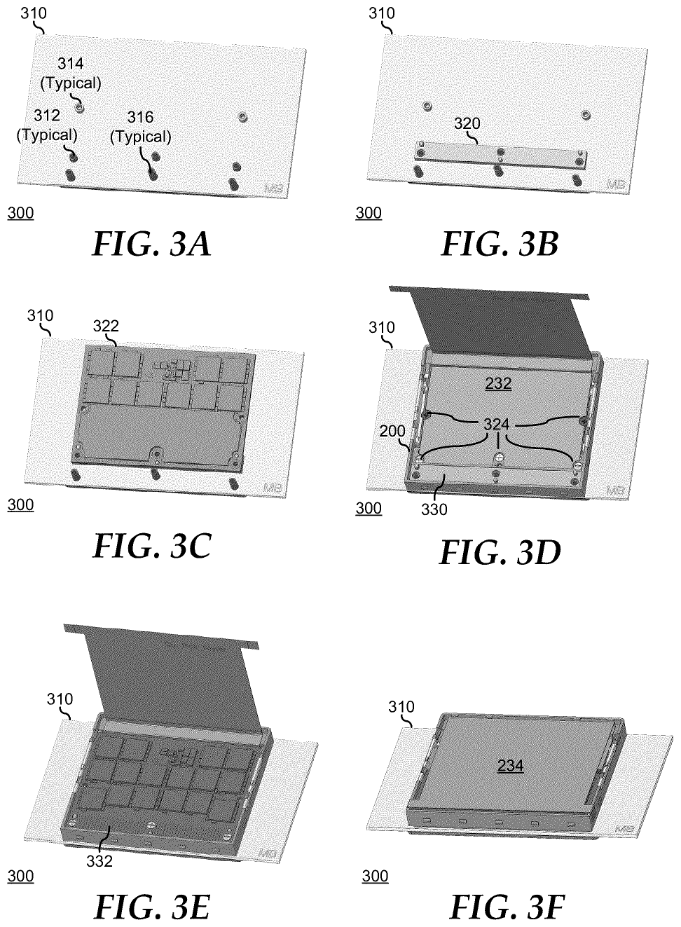

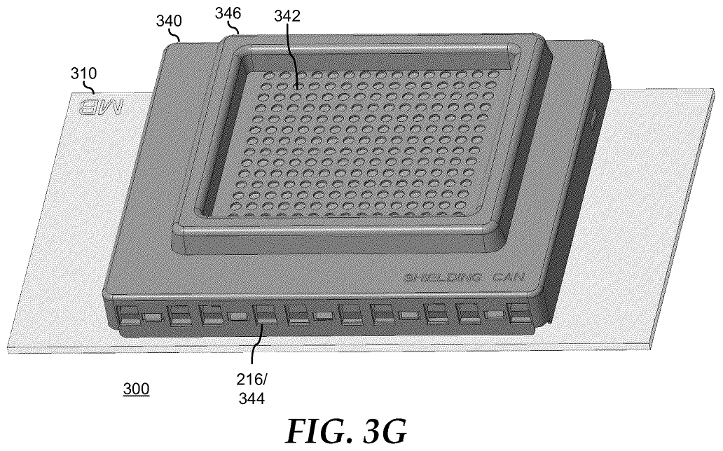

FIG. 2C illustrates a typical retention plate 220. Retention plate 220 may be formed of a stamped sheet metal plate of a suitable metal material to maintain the desired form and to provide grounding interconnections between the bottom CAMM, the top CAMM, and a metal shield can 340, as shown in FIG. 3G, below. Shield can 340 includes top vent holes 342 in a top surface of the shield can, front vent holes 344 in the front side of the shield can and collocated with vent holes 216 in the front side of CAMM carrier 210, and an air duct 346 around the top vent holes. The functions and features of retention plate 220 will be described below. Retention plate 220 includes a hooked profile 221, bottom CAMM contact springs 222, a bottom CAMM retention screw hole 224, top CAMM contact springs 226, and a shielding can contact spring 228. Hooked profile 221 is provided to mount and firmly affix retention plate 220 to the side wall of CAMM carrier 210, as illustrated in FIG. 2D. The functions and features of bottom CAMM contact springs 222, bottom CAMM retention screw hole 224, and top CAMM contact springs 226, and shielding can contact spring 228 will be described below.

CAMM holder 200 further includes a foil layer 230. FIG. 2E illustrates a back view of CAMM holder 200 with foil layer 230 affixed to foil mounting ledge 214, and FIG. 2F illustrates a front view of the CAMM holder with the foil layer affixed to the foil mounting ledge. Foil layer 230 includes a bottom CAMM covering section 232 and a top CAMM covering section 234. Foil layer 230 represents a foil sheet fabricated of a suitable material to provide the desired functionality for the foil layer. For example, where foil layer 230 is provided to shield the top and bottom CAMM from each other from electromagnetic interference (EMI) or to carry heat away from the CAMMs, as described further below, the foil layer may be fabricated to include a metal layer, such as a copper foil. In another example, where foil layer 230 is provided to electrically insulate the top and bottom CAMM from each other, the foil layer may be fabricated to include an insulating material, such as a Mylar foil. In other examples, foil layer 230 may be fabricated to include both a metal layer and an insulating layer, as needed or desired. Foil layer 230 may be affixed to foil mounting ledge 214 by any suitable adhesive as needed or desired. Note that foil layer 230 is illustrated as a single foil layer. However, it will be understood that bottom CAMM covering section 232 and top CAMM covering section 234 may consist of one or more separate sheet of the foil material, as needed or desired.

FIGS. 3A-3G illustrate the assembly of an information handling system 300 utilizing CAMM holder 200. In a first step, illustrated in FIG. 3A, a motherboard 310 is prepared with bottom CAMM connector stand-offs 312, bottom CAMM mounting stand-offs 314, and top CAMM connector stand-offs 316. A bottom CAMM compression connector 320 is placed over bottom CAMM connector stand-offs 312 of FIG. 3B, and a bottom CAMM 322 is located atop bottom CAMM connector stand-offs 312, bottom CAMM mounting stand-offs 314, and bottom CAMM compression connector 320 in FIG. 3C. In FIG. 3D, CAMM holder 200 is placed atop the bottom CAMM 322, and the bottom CAMM and the CAMM holder are secured to motherboard 310 with three (3) screws 324 to bottom CAMM connector stand-offs 312 and with two (2) screws 324 to bottom CAMM mounting stand-offs 314. Also shown in FIG. 3D, a top CAMM compression connector 330 is placed over top CAMM connector stand-offs 316.

A top CAMM 332 is located atop top CAMM connector stand-offs 316, and within a recess in CAMM holder 200 in FIG. 3E. The bottom CAMM covering portion 232 of foil layer 230 is located between bottom CAMM 322 and top CAMM 332. In FIG. 3F, top CAMM covering portion 234 of foil layer 230 is placed atop top CAMM 332. Shielding can 340 is affixed atop CAMM holder 200 in FIG. 3G. Note that as illustrated in FIGS. 3A-3G, top CAMM 322 and bottom CAMM 332 are represented as large footprint CAMMs (such as 64 Gigabyte (GB) CAMMs), but this is not necessarily so, and that the CAMMs so assembled may include large footprint CAMMs, small footprint CAMMs (such as 8 GB CAMMs), CAMMs with other intermediate footprints, or a combination thereof, as needed or desired.

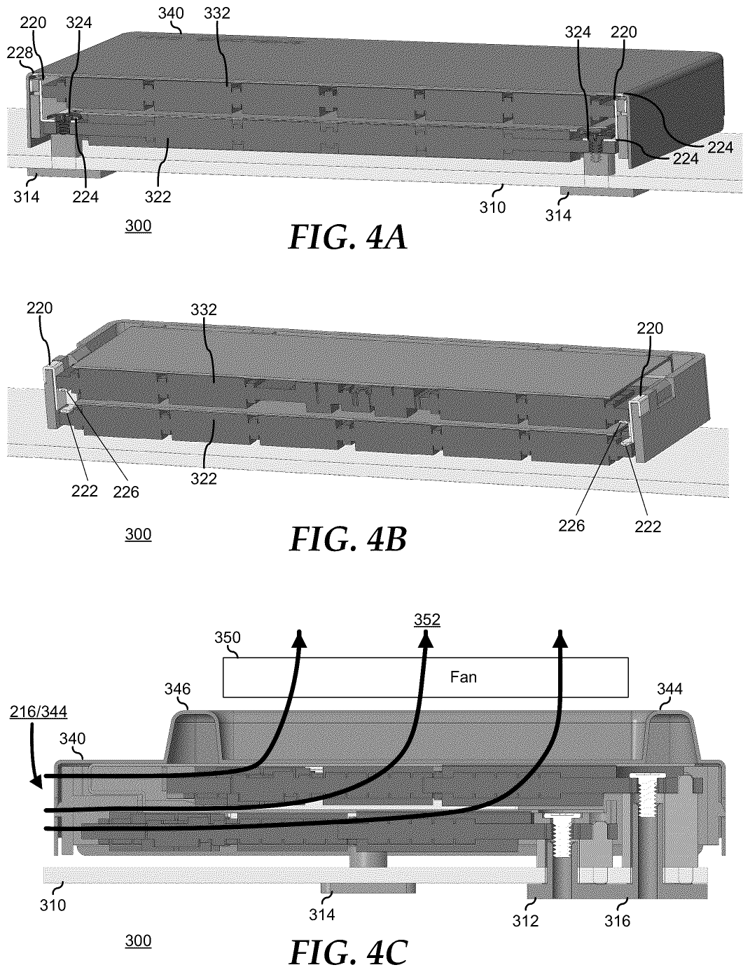

FIGS. 4A-4C show information handling system 300 having top CAMM 332 securely affixed to motherboard 310. In particular, FIG. 4A illustrates a cut-away view of information handling system 300 through retention plate 220, and more particularly through bottom CAMM retention screw hole 224. Bottom CAMM 322 is secured to motherboard 310 with screws 324 into bottom CAMM mounting stand-offs 314, and the bending loads from any cantilevered portion of the bottom CAMM are transferred to the motherboard, as may be typical for mounting a bottom CAMM in a stacked CAMM arrangement.

Additionally, CAMM carrier 210, and particularly retention plate 220, is likewise secured to motherboard 310 with screws 324 into bottom CAMM mounting stand-offs 314, making the retention plate a load-bearing element. FIG. 4B illustrates a cut-away view of information handling system 300 through retention plate 220, and particularly through bottom CAMM retention springs 222 and top CAMM retention springs 226. Top CAMM 332 is placed atop top CAMM retention springs 226. Here, the mechanical rigidity of retention plate 220, and particularly between bottom CAMM retention springs 222 and top CAMM retention springs 226, provides a support element, such that and the bending loads from any cantilevered portion of the top CAMM are transferred to the retention plate and thereby to motherboard 310. It will be further understood that top CAMM 332 is secured within the recess in CAMM holder 200 by one or more retention hooks 212, as illustrated in FIG. 2D. Thus the stacked CAMM mounting arrangement as illustrated by information handling system 300, and particularly the mechanical support provided by CAMM carrier 210 and retention plate 220, provides a mechanism to securely affix top CAMM 332 to motherboard 310.

The arrangement as illustrated by information handling system 300 further operates to ensure adequate shield grounding between motherboard 310, bottom CAMM 322, top CAMM 332, and shield can 340. In particular, FIG. 4A illustrates where bottom CAMM 322 is secured to motherboard 310 with screws 324 into bottom CAMM mounting stand-offs 314. Here, bottom CAMM mounting stand-offs 314 are illustrated as including bolsters on the bottom side of the motherboard 310. Motherboard 310 is configured to include ground pads that are connected to a ground plane of the motherboard and that are collocated to contact the bolster portion of bottom CAMM mounting stand-offs 314. As such, where bottom CAMM mounting stand-offs 314 are fabricated of a conductive material, such as a metal material, then the bottom CAMM mounting stand-offs provide a grounded contact. As such, where screws 324 are also fabricated of a conductive material, then retention plate 220 further provides a grounded contact. Further, where shield can 340 is fabricated of a conductive material, then the shield can is grounded through contact with shielding can contact spring 228.

Finally, where bottom CAMM 322 and top CAMM 332 include ground contacts that are collocated with bottom CAMM contact springs 222 and with top CAMM contact springs 226, then the top and bottom CAMMs are grounded to the common ground plane of motherboard 310. As such, the stacked CAMM mounting arrangement as illustrated by information handling system 300, and particularly the grounding provided by retention plate 220, provides a grounding mechanism to ground bottom CAMM 322, top CAMM 332, and shield can 340 to motherboard 310. In prior art applications, the shield can is provided with a depth sufficient to extend to the motherboard to make contact with a ground contact on the motherboard to ground the shield can. Shield can 340 is fabricated with a depth that does not extend to contact motherboard 310, as illustrated in FIG. 4C. Note that the bolsters may be configured such as a part of bottom CAMM mounting stand-offs 314, or may be separate from the bottom CAMM mounting stand-offs, as needed or desired.

FIG. 4C shows information handling system 300 including a fan 350 that is located above shield can 340, and more particularly is located above the portion of the shield can that includes top vent holes 342. Fan 350 is configured to draw an airflow 352 from vent holes 216/344, through bottom CAMM 322 and top CAMM 332, and upward through top vent holes 346 and through the fan. In a particular embodiment, vent holes 216 open up 20-40% of the front surface of CAMM carrier 210, front vent holes 344 open up 20-40% of the front surface of shield can 340, and top vent holes 344 open up 20-40% of the top surface of the shield can. In another embodiment, vent holes 216 open up 30% of the front surface of CAMM carrier 210, front vent holes 344 open up 30% of the front surface of shield can 340, and top vent holes 344 open up 30% of the top surface of the shield can. In addition, where foil layer 230 is fabricated to include a metal layer, such as a copper foil, the foil layer operates to carry heat away from bottom CAMM 322 and top CAMM 332.

It has been understood by the inventors of the current embodiments that a typical stacked CAMM arrangement may exhibit hot spots, particularly on the bottom CAMM, with temperatures in excess of 92° C. However, the inclusion of a foil layer similar to foil layer 230 may bring the hot spot temperatures down to around 81° C. Also, the inclusion of the foil layer and a shield can without venting results in hot spots in excess of 85.5° C. On the other hand, where the shield can includes vent holes, such as with shield can 340, said hot spots exhibit temperatures down around 79° C., and a reduction in other hot spots of around 6° C. Finally, the inclusion of an air duct structure in the shield can, such as air duct 346, results in a further decrease in hot spot temperature of between 12-14° C., where the depth of the air duct was fabricated at 8 millimeters.

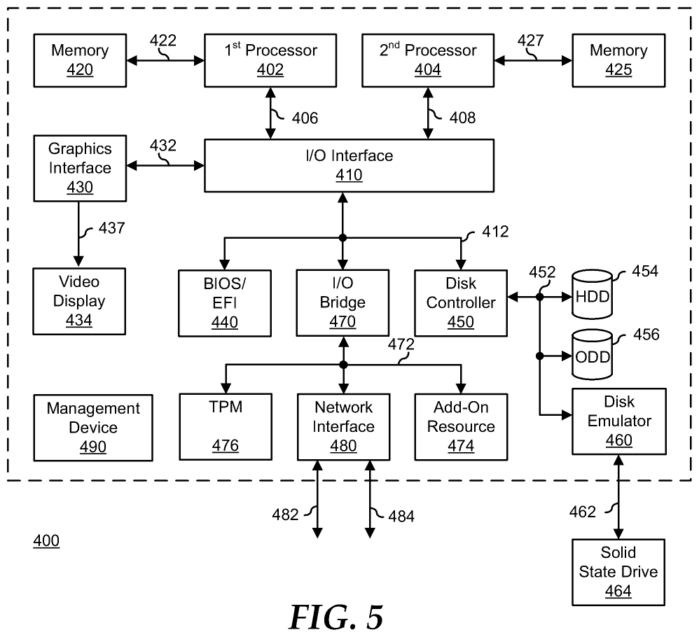

FIG. 5 illustrates a generalized embodiment of an information handling system 400 similar to information handling system 400. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 400 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 400 can include processing resources for executing machine-executable code, such as a central processing unit (CPU), a programmable logic array (PLA), an embedded device such as a System-on-a-Chip (SoC), or other control logic hardware. Information handling system 400 can also include one or more computer-readable medium for storing machine-executable code, such as software or data. Additional components of information handling system 400 can include one or more storage devices that can store machine-executable code, one or more communications ports for communicating with external devices, and various input and output (I/O) devices, such as a keyboard, a mouse, and a video display. Information handling system 400 can also include one or more buses operable to transmit information between the various hardware components.

Information handling system 400 can include devices or modules that embody one or more of the devices or modules described below, and operates to perform one or more of the methods described below. Information handling system 400 includes a processors 402 and 404, an input/output (I/O) interface 410, memories 420 and 425, a graphics interface 430, a basic input and output system/universal extensible firmware interface (BIOS/UEFI) module 440, a disk controller 450, a hard disk drive (HDD) 454, an optical disk drive (ODD) 456, a disk emulator 460 connected to an external solid state drive (SSD) 462, an I/O bridge 470, one or more add-on resources 474, a trusted platform module (TPM) 476, a network interface 480, a management device 490, and a power supply 495. Processors 402 and 404, I/O interface 410, memory 420, graphics interface 430, BIOS/UEFI module 440, disk controller 450, HDD 454, ODD 456, disk emulator 460, SSD 462, I/O bridge 470, add-on resources 474, TPM 476, and network interface 480 operate together to provide a host environment of information handling system 400 that operates to provide the data processing functionality of the information handling system. The host environment operates to execute machine-executable code, including platform BIOS/UEFI code, device firmware, operating system code, applications, programs, and the like, to perform the data processing tasks associated with information handling system 400.

In the host environment, processor 402 is connected to I/O interface 410 via processor interface 406, and processor 404 is connected to the I/O interface via processor interface 408. Memory 420 is connected to processor 402 via a memory interface 422. Memory 425 is connected to processor 404 via a memory interface 427. Graphics interface 430 is connected to I/O interface 410 via a graphics interface 432, and provides a video display output 436 to a video display 434. In a particular embodiment, information handling system 400 includes separate memories that are dedicated to each of processors 402 and 404 via separate memory interfaces. An example of memories 420 and 430 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 440, disk controller 450, and I/O bridge 470 are connected to I/O interface 410 via an I/O channel 412. An example of I/O channel 412 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 410 can also include one or more other I/O interfaces, including an Industry Standard Architecture (ISA) interface, a Small Computer Serial Interface (SCSI) interface, an Inter-Integrated Circuit (I2C) interface, a System Packet Interface (SPI), a Universal Serial Bus (USB), another interface, or a combination thereof. BIOS/UEFI module 440 includes BIOS/UEFI code operable to detect resources within information handling system 400, to provide drivers for the resources, initialize the resources, and access the resources. BIOS/UEFI module 440 includes code that operates to detect resources within information handling system 400, to provide drivers for the resources, to initialize the resources, and to access the resources.

Disk controller 450 includes a disk interface 452 that connects the disk controller to HDD 454, to ODD 456, and to disk emulator 460. An example of disk interface 452 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 460 permits SSD 464 to be connected to information handling system 400 via an external interface 462. An example of external interface 462 includes a USB interface, an IEEE 1394 (Firewire) interface, a proprietary interface, or a combination thereof. Alternatively, solid-state drive 464 can be disposed within information handling system 400.

I/O bridge 470 includes a peripheral interface 472 that connects the I/O bridge to add-on resource 474, to TPM 476, and to network interface 480. Peripheral interface 472 can be the same type of interface as I/O channel 412, or can be a different type of interface. As such, I/O bridge 470 extends the capacity of I/O channel 412 where peripheral interface 472 and the I/O channel are of the same type, and the I/O bridge translates information from a format suitable to the I/O channel to a format suitable to the peripheral channel 472 where they are of a different type. Add-on resource 474 can include a data storage system, an additional graphics interface, a network interface card (NIC), a sound/video processing card, another add-on resource, or a combination thereof. Add-on resource 474 can be on a main circuit board, on separate circuit board or add-in card disposed within information handling system 400, a device that is external to the information handling system, or a combination thereof.

Network interface 480 represents a NIC disposed within information handling system 400, on a main circuit board of the information handling system, integrated onto another component such as I/O interface 410, in another suitable location, or a combination thereof. Network interface device 480 includes network channels 482 and 484 that provide interfaces to devices that are external to information handling system 400. In a particular embodiment, network channels 482 and 484 are of a different type than peripheral channel 472 and network interface 480 translates information from a format suitable to the peripheral channel to a format suitable to external devices. An example of network channels 482 and 484 includes InfiniBand channels, Fibre Channel channels, Gigabit Ethernet channels, proprietary channel architectures, or a combination thereof. Network channels 482 and 484 can be connected to external network resources (not illustrated). The network resource can include another information handling system, a data storage system, another network, a grid management system, another suitable resource, or a combination thereof.

Management device 490 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 400. In particular, management device 490 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 400, such as system cooling fans and power supplies. Management device 490 can include a network connection to an external management system, and the management device can communicate with the management system to report status information for information handling system 400, to receive BIOS/UEFI or system firmware updates, or to perform other task for managing and controlling the operation of information handling system 400. Management device 490 can operate off of a separate power plane from the components of the host environment so that the management device receives power to manage information handling system 400 where the information handling system is otherwise shut down. An example of management device 490 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (IDRAC), an Embedded Controller (EC), or the like. Management device 490 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A holder for stacked compression attached memory modules (CAMMs), the holder comprising:
a carrier including a first recessed area for receiving a bottom one of the CAMMs, a second recessed area for receiving a top one of the CAMMs, and a first vent hole in a side of the carrier; and
a shield can configured to fit atop the carrier, the shield can including a second vent hole in a side of the shield can, the second vent hole being collocated with the first vent hole, the first vent hole and the second vent hole to cool the bottom CAMM and the top CAMM.

2. The holder of claim 1, wherein the shield can further includes a third vent hole in a top side of the shield can to further cool the bottom CAMM and the top CAMM.

3. The holder of claim 2, further comprising:
a fan situated atop the third vent hole.

4. The holder of claim 3, wherein the fan creates an airflow from the first and second vent holes, over the bottom CAMM and the top CAMM and through the third vent hole.

5. The holder of claim 1, wherein the shield can further includes an air duct in a top side of the shield can.

6. The holder of claim 1, further comprising:
a first foil layer situated between the bottom CAMM and the top CAMM.

7. The holder of claim 6, wherein the first foil layer includes a metallic material to conduct heat from the bottom CAMM and the top CAMM.

8. The holder of claim 7, further comprising:
a second foil layer situated atop the top CAMM.

9. The holder of claim 8, wherein the second foil layer includes the metallic material to conduct heat from the top CAMM.

10. The holder of claim 9, wherein the first and second foil layers are formed of a common foil layer.

11. A method for cooling stacked compression attached memory modules (CAMMs), the method comprising:
installing a bottom one of the CAMMs to a motherboard;
installing a carrier atop the bottom CAMM, wherein the carrier includes a first vent hole in a side of the carrier;
installing a top one of the CAMMs into the carrier;
installing a shield can atop the carrier, wherein the shield includes a second vent hole in a side of the shield can, and wherein the second vent hole is collocated with the first vent hole; and
cooling the bottom CAMM and the top CAMM through the first vent hole and the second vent hole.

12. The method of claim 11, wherein the shield can further includes at least one third vent hole in a top side of the shield can to further cool the bottom CAMM and the top CAMM.

13. The method of claim 12, further comprising situating a fan atop the third vent hole.

14. The method of claim 13, further comprising creating, by the fan, an airflow from the first and second vent holes, over the bottom CAMM and the top CAMM and through the third vent hole.

15. The method of claim 11, wherein the shield can further includes an air duct in a top side of the shield can.

16. The method of claim 11, further comprising providing a first foil layer situated between the bottom CAMM and the top CAMM.

17. The method of claim 16, wherein the first foil layer includes a metallic material to conduct heat from the bottom CAMM and the top CAMM.

18. The method of claim 17, further comprising providing a second foil layer situated atop the top CAMM.

19. The method of claim 18, wherein the second foil layer includes the metallic material to conduct heat from the top CAMM.

20. An information handling system, comprising:
a motherboard;
a bottom compression attached memory module (CAMM);
a top CAMM; and
a holder to stack the bottom CAMM and the top CAMM, the holder including:
a carrier including a first recessed area for receiving the bottom CAMM, a second recessed area for receiving the top CAMM, and a first vent hole in a side of the carrier; and
a shield can configured to fit atop the carrier, the shield can including a second vent hole in a side of the shield can, the second vent hole being collocated with the first vent hole, the first vent hole and the second vent hole to cool the bottom CAMM and the top CAMM.
